(19) United States
(12) Patent Application Publication
(10) Pub. No.: US 2025/0201516 A1
(43) Pub. Date: Jun. 19, 2025

(54) PLASMA GENERATION MODULE, OPERATION METHOD THEREOF, AND SUBSTRATE PROCESSING APPARATUS

(71) Applicant: SEMES CO., LTD., Cheonan-si (KR)

(72) Inventor: Je Ho KIM, Cheonan-si (KR)

(73) Assignee: SEMES CO., LTD., Cheonan-si (KR)

(21) Appl. No.: 18/971,377

(22) Filed: Dec. 6, 2024

(30) Foreign Application Priority Data
Dec. 15, 2023 (KR) 10-2023-0183071

(51) Int. Cl. H01J 37/32

(52) U.S. Cl. CPC H01J 37/3211

(57) ABSTRACT

Disclosed are a plasma generation module capable of controlling the plasma characteristics in the edge area in a processing space in a process chamber, an operation method of the plasma generation module, and a substrate processing apparatus including the plasma generation module. The plasma generation module for generating plasma in a substrate processing apparatus configured to process a substrate using plasma includes a housing disposed on an upper portion of a process chamber having defined therein a processing space for processing of the substrate, the housing having an open bottom and a processing space defined therein, an antenna disposed in the processing space in the housing to apply radio-frequency (RF) power to the interior of the process chamber, an RF power supply configured to supply the RF power to the antenna, and a metal ring assembly configured to control linkage of a magnetic field generated by the antenna.

### CROSS-REFERENCE TO THE RELATED APPLICATION

The present application claims priority to and the benefit of Korean Patent Application No. 10-2023-0183071, filed on Dec. 15, 2023, in the Korean Intellectual Property Office, the entire disclosure of which is incorporated herein by reference.

### BACKGROUND

### Technical Field

The present disclosure relates to a plasma generation module for generating plasma for processing of a substrate, an operation method of the plasma generation module, and a substrate processing apparatus including the plasma generation module.

### Description of the Related Art

A semiconductor manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

A plasma generation module for generating plasma is disposed on an upper portion of a process chamber having a processing space for processing the substrate. The plasma generation module generates plasma by exciting a process gas present in a processing space in the process chamber. An inductively coupled plasma (ICP) type plasma generation module generates an electromagnetic field using an antenna including a plurality of coils. The characteristics of the plasma generated by the antenna are determined by a magnetic flux interlinking the coils.

In the edge area in the processing space in the process chamber, the intensity of plasma is low and the plasma is not evenly distributed due to the influence of the inner wall of the process chamber, as compared to in the central area in the processing space in the process chamber.

### SUMMARY

The present disclosure provides a plasma generation module capable of controlling the plasma characteristics in the edge area in a processing space in a process chamber, an operation method of the plasma generation module, and a substrate processing apparatus including the plasma generation module.

In accordance with an aspect of the present disclosure, a plasma generation module for generating plasma in a substrate processing apparatus configured to process a substrate using plasma includes a housing disposed on an upper portion of a process chamber having a processing space for processing the substrate, an antenna disposed in the housing, the antenna being configured to apply radio-frequency (RF) power to the processing space, an RF power supply configured to supply the RF power to the antenna, and a metal ring assembly configured to control linkage of a magnetic field generated by the antenna.

In the plasma generation module according to the embodiment of the present disclosure, the metal ring assembly may include a metal ring having a larger diameter than the antenna, the metal ring being located between the antenna and a wall of the housing, a vertical drive shaft connected to an upper end of the metal ring, and a drive mechanism configured to move the metal ring in a vertical direction through the vertical drive shaft.

In the plasma generation module according to the embodiment of the present disclosure, the vertical drive shaft may extend upward from an upper surface of the metal ring to pass through a ceiling of the housing, and the drive mechanism may be coupled to an upper surface of the ceiling of the housing.

In the plasma generation module according to the embodiment of the present disclosure, the drive mechanism may be implemented as a motor or a cylinder.

In the plasma generation module according to the embodiment of the present disclosure, the metal ring may include a plurality of metal rings disposed concentrically with each other while having different diameters.

In the plasma generation module according to the embodiment of the present disclosure, a metal ring to be located between the antenna and the wall of the housing may be determined from among the plurality of metal rings based on plasma distribution in the edge area of the process chamber.

In the plasma generation module according to the embodiment of the present disclosure, the metal ring may include a plurality of ring segments separated from each other in a horizontal direction.

In the plasma generation module according to the embodiment of the present disclosure, a ring segment to be located between the antenna and the wall of the housing may be determined from among the plurality of ring segments based on plasma distribution in the edge area of the process chamber.

In the plasma generation module according to the embodiment of the present disclosure, the metal ring may be made of a Permalloy alloy.

In accordance with another aspect of the present disclosure, a method of operating the plasma generation module for generating plasma in a substrate processing apparatus configured to process a substrate using plasma includes placing the metal ring in a space between the antenna and the wall of the housing and applying RF power to the antenna.

In accordance with a further aspect of the present disclosure, a substrate processing apparatus for processing a substrate using plasma includes a process chamber including a body defining a processing space and a sealing cover covering an open top of the body, a substrate support member disposed in the body, the substrate support being configured to support the substrate, a gas supply module configured to supply process gas to the processing space, and a plasma generation module configured to apply RF power to the processing space to excite the process gas supplied to the processing space.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows the structure of a substrate processing apparatus according to the present disclosure;

FIG. 2 is a view for explaining linkage of a magnetic field in accordance with a distance between an antenna and an inner wall of a housing;

FIG. 3 is a view for explaining linkage of a magnetic field in a plasma generation module in the state in which a metal ring is located between the antenna and the housing;

FIG. 4 shows the cross-section taken along line A-A′ in FIG. 1;

FIG. 5 shows the structure of a substrate processing apparatus including a metal ring assembly including a plurality of metal rings;

FIG. 6 is a view for explaining linkage of a magnetic field in the plasma generation module in the state in which the plurality of metal rings is located between the antenna and the housing;

FIG. 7 shows the cross-section taken along line A-A′ in FIG. 5;

FIG. 8 shows the cross-section taken along line A-A′ in FIG. 1 when the metal ring includes a plurality of ring segments;

FIG. 9 shows the cross-section taken along line A-A′ in FIG. 5 when the metal ring includes a plurality of metal rings and each of the metal rings includes a plurality of ring segments; and

FIG. 10 is a flowchart showing an operation method of a plasma generation module according to the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

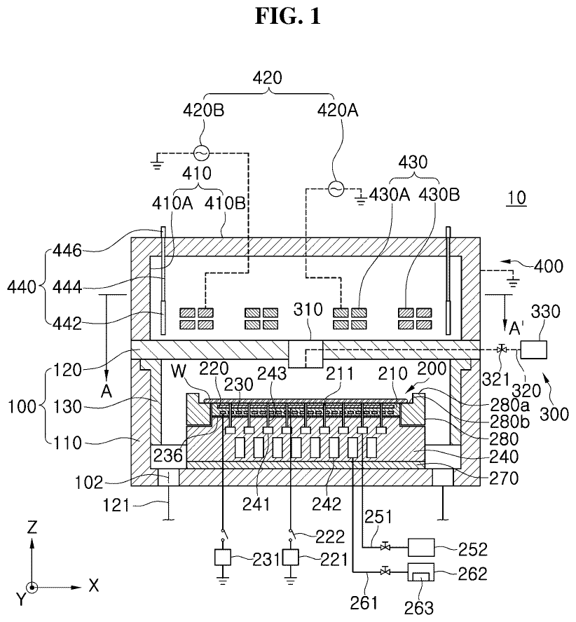

FIG. 1 shows the structure of a substrate processing apparatus 10 according to the present disclosure. FIG. 1 is a cross-sectional view of the substrate processing apparatus 10 when viewed from the side. In FIG. 1, a first horizontal direction X and a second horizontal direction Y are directions in which the substrate W is placed, and are perpendicular to each other. A vertical direction Z is a direction perpendicular both to the first horizontal direction X and to the second vertical direction Y. That is, the vertical direction Z is a direction perpendicular to the plane on which the substrate W is placed.

Referring to FIG. 1, the substrate processing apparatus 10 processes the substrate W using plasma. The substrate processing apparatus 10 includes a process chamber 100, a substrate support member 200, a gas supply module 300, and a plasma generation module 400.

The process chamber 100 defines a space in which a process of processing the substrate W is performed. The process chamber 100 includes a body 110, a sealing cover 120, and a liner 130.

A processing space with an open top is defined in the body 110. The processing space in the body 110 is provided as a space in which a process of processing the substrate W is performed. The body defines a processing space. The body 110 is made of metal. The body 110 may be made of aluminum. An exhaust hole 102 is formed in the bottom surface of the body 110. The exhaust hole 102 is connected to an exhaust line 121. Reaction by-products generated during the processing process and gases remaining in the processing space in the body 110 may be discharged to the outside through the exhaust line 121. During the exhaust process, the pressure in the body 110 is reduced to a predetermined pressure.

A sealing cover 120 is disposed on the body 110. The sealing cover 120 covers the open top of the body 110. The liner 130 defines a space with an open top and bottom. The liner 130 may be formed in a cylindrical shape. The liner 130 may have a radius corresponding to the inner side surface of the body 110. The liner 130 is provided along the inner side surface of the body 110. A support ring 131 is formed on the upper end of the liner 130. The support ring 131 is formed as a ring-shaped plate, and serves to join the liner 130 to the body 110. The liner 130 may be made of the same material as the body 110. The liner 130 may be made of aluminum. The liner 130 protects the inner side surface of the body 110. In the process of exciting the process gas, arc discharge occurs in the process chamber 100. Arc discharge may damage peripheral devices. The liner 130 may be a device that is inexpensive and easy to replace compared to the body 110. Therefore, if the liner 130 is damaged due to arc discharge, the liner 130 may be replaced with a new one.

The substrate support member 200 is disposed in the body 110. The substrate support member 200 supports the substrate W. The substrate support member 200 may be configured as an electrostatic chuck that holds the substrate W using electrostatic force.

The substrate support member 200 includes a dielectric plate 210, an electrostatic electrode 220, a heater 230, a support plate 240, and an insulating plate 270. The dielectric plate 210 is located at the top of the substrate support member 200. The dielectric plate 210 is provided as a disc-shaped dielectric substance. The substrate W is placed on the upper surface of the dielectric plate 210. The upper surface of the dielectric plate 210 has a smaller diameter than the substrate W. Thus, the edge area of the substrate W is located outside the dielectric plate 210. A first supply flow path 211 is formed in the dielectric plate 210. The first supply flow path 211 is formed from the upper surface of the dielectric plate 210 to the lower surface of the dielectric plate 210. A plurality of first supply flow paths 211 may be formed so as to be spaced apart from each other, and may serve as passages through which a heat transfer medium (e.g., helium (He)) is supplied to the lower surface of the substrate W.

The electrostatic electrode 220 and the heater 230 are embedded in the dielectric plate 210. The electrostatic electrode 220 is located above the heater 230. The electrostatic electrode 220 is electrically connected to a first lower power supply 221. The first lower power supply 221 is configured as a direct current (DC) power supply. A switch 222 is mounted between the electrostatic electrode 220 and the first lower power supply 221. The electrostatic electrode 220 may be electrically connected to the first lower power supply 221 through on/off operation of the switch 222. When the switch 222 is turned on, direct current is supplied to the electrostatic electrode 220. Electrostatic force is exerted between the electrostatic electrode 220 and the substrate W by the current supplied to the electrostatic electrode 220, and the substrate W is attracted to and tightly held by the dielectric plate 210 due to the electrostatic force.

The heater 230 is electrically connected to a second lower power supply 231. The heater 230 resists current applied thereto from the second lower power supply 231 to generate heat. The generated heat is transferred to the substrate W through the dielectric plate 210. The temperature of the substrate W is adjusted to a predetermined temperature by the heat generated by the heater 230. The heater 230 is configured as a spiral coil. The heater 230 may have a regular spiral interval and may be mounted in the dielectric plate 210.

The support plate 240 is located under the dielectric plate 210. The lower surface of the dielectric plate 210 and the upper surface of the support plate 240 may be adhered to each other by means of an adhesive 236. The support plate 240 may be made of metal (e.g., aluminum). The upper surface of the support plate 240 may be stepped such that the central area thereof is located at a position higher than the edge area thereof. The central area of the upper surface of the support plate 240 has an area corresponding to the lower surface of the dielectric plate 210, and is adhered to the lower surface of the dielectric plate 210. A first circulation flow path 241, a second circulation flow path 242, and a second supply flow path 243 may be formed in the support plate 240.

The first circulation flow path 241 is provided as a passage through which a heat transfer medium (e.g., helium (He)) circulates. The first circulation flow path 241 may be formed in a spiral shape in the support plate 240. Alternatively, a plurality of ring-shaped first circulation flow paths 241 having different radii may be disposed concentrically with each other. The first circulation flow paths 241 may communicate with each other. The first circulation flow paths 241 are formed at the same height.

The second circulation flow path 242 is provided as a passage through which cooling fluid (e.g., refrigerant) circulates. The second circulation flow path 242 may be formed in a spiral shape in the support plate 240. Alternatively, a plurality of ring-shaped second circulation flow paths 242 having different radii may be disposed concentrically with each other. The second circulation flow paths 242 may communicate with each other. The second circulation flow paths 242 may have a greater cross-sectional area than the first circulation flow paths 241. The second circulation flow paths 242 are formed at the same height. The second circulation flow paths 242 may be located below the first circulation flow paths 241.

A plurality of second supply flow paths 243 extends upward from the first circulation flow paths 241 to the upper surface of the support plate 240. The number of second supply flow paths 243 is identical to the number of first supply flow paths 211. The second supply flow paths 243 connect the first circulation flow paths 241 to the first supply flow paths 211.

The first circulation flow path 241 is connected to a heat transfer medium storage unit 252 via a heat transfer medium supply line 251. A cooling fluid storage unit 262 stores cooling fluid. A cooler 263 may be provided in the cooling fluid storage unit 262. The cooler 263 cools the cooling fluid to a predetermined temperature. Alternatively, the cooler 263 may be mounted on a cooling fluid supply line 261. The cooling fluid supplied to the second circulation flow path 242 through the cooling fluid supply line 261 circulates along the second circulation flow path 242 to cool the support plate 240. As the support plate 240 is cooled, the dielectric plate 210 and the substrate W are also cooled, whereby the temperature of the substrate W is maintained at a predetermined temperature.

The insulating plate 270 is disposed under the support plate 240. The insulating plate 270 is formed to have a size corresponding to the support plate 240. The insulating plate 270 is located between the support plate 240 and the bottom surface of the process chamber 100. The insulating plate 270 is made of an insulative material, and electrically insulates the support plate 240 and the process chamber 100 from each other.

A focus ring 280 is disposed in the edge area of the substrate support member 200. The focus ring 280 has a ring shape and is disposed along the periphery of the dielectric plate 210. The upper surface of the focus ring 280 may be stepped such that an outer side portion 280a thereof is located at a higher position than an inner side portion 280b thereof. The upper surface of the inner side portion 280b of the focus ring 280 is located at the same height as the upper surface of the dielectric plate 210. The upper surface of the inner side portion 280b of the focus ring 280 supports the edge area of the substrate W located outside the dielectric plate 210. The outer side portion 280a of the focus ring 280 is formed so as to surround the edge area of the substrate W. The focus ring 280 expands an area in which the electromagnetic field is formed so that the substrate W is located at the center of the area in which plasma is formed. Accordingly, plasma is evenly formed over the entire area of the substrate W, and as a result, the entire area of the substrate W is evenly processed.

The gas supply module 300 supplies process gas to the processing space of the process chamber 100. The gas supply module 300 includes a gas supply nozzle 310, a gas supply line 320, and a gas storage unit 330. The gas supply nozzle 310 is mounted to the central portion of the sealing cover 120. A spray port is formed in the bottom surface of the gas supply nozzle 310. The spray port is located below the sealing cover 120, and supplies the process gas to the processing space of the process chamber 100. The gas supply line 320 connects the gas supply nozzle 310 to the gas storage unit 330. The gas supply line 320 supplies the process gas stored in the gas storage unit 330 to the gas supply nozzle 310. A valve 321 may be mounted on the gas supply line 320. The valve 321 may control opening and closing of the gas supply line 320, and may also control the flow rate of the process gas supplied through the gas supply line 320.

The plasma generation module 400 applies radio-frequency (RF) power to the processing space of the process chamber 100 to excite the process gas supplied to the processing space of the process chamber 100. The plasma generation module 400 includes a housing 410, an RF power supply 420, an antenna 430, and a metal ring assembly 440.

The housing 410 has an open bottom and has a processing space defined therein. The housing 410 is located on the sealing cover 120. In detail, the housing 410 is disposed on the upper surface of the sealing cover 120. The interior of the housing 410 is provided as a space in which the antenna 430 is located. The housing 410 may be grounded. The housing 410 includes a wall 410A extending in the vertical direction Z and a ceiling 410B extending in the horizontal direction from the upper end of the wall 410A.

The RF power supply 420 generates RF current. The RF current generated by the RF power supply 420 is applied to the antenna 430. The antenna 430 applies RF power to the processing space of the process chamber 100. The RF power supply 420 includes a first RF power supply 420A and a second RF power supply 420B. The first RF power supply 420A and the second RF power supply 420B may supply RF power having different frequencies or different magnitudes. The first RF power supply 420A supplies first RF power to an inner antenna 430A, and the second RF power supply 420B supplies second RF power to an outer antenna 430B.

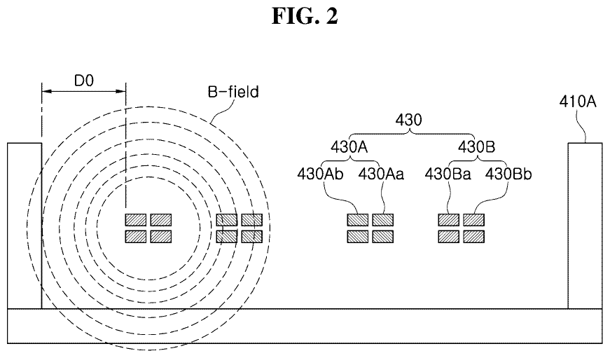

The antenna 430 includes an inner antenna 430A and an outer antenna 430B. Referring to FIG. 2, the inner antenna 430A includes an inner coil 430Aa and an outer coil 430Ab, and the outer antenna 430B includes an inner coil 430Ba and an outer coil 430Bb. The inner antenna 430A may be formed such that two or more inner coils 430Aa are stacked in the vertical direction Z and two or more outer coils 430Ab are stacked in the vertical direction Z, and the outer antenna 430B may be formed such that two or more inner coils 430Ba are stacked in the vertical direction Z and two or more outer coils 430Bb are stacked in the vertical direction Z. The inner antenna 430A receives the first RF power from the first RF power supply 420A, and the outer antenna 430B receives the second RF power from the second RF power supply 420B.

FIG. 2 is a view for explaining linkage of a magnetic field in accordance with a distance between the antenna 430 and the inner wall of the housing 410.

Linkage of a magnetic field B-field generated by the antenna 430 is determined by a distance DO between the outer side end of the antenna 430 and a wall 410A of the housing 410. In detail, the shorter the distance DO between the antenna 430 and the wall 410A of the housing 410, the greater the linkage. The greater the linkage, the smaller the amount of power transmitted to plasma. Conversely, the longer the distance DO between the antenna 430 and the wall 410A of the housing 410, the less the linkage. The less the linkage, the larger the amount of power transmitted to plasma.

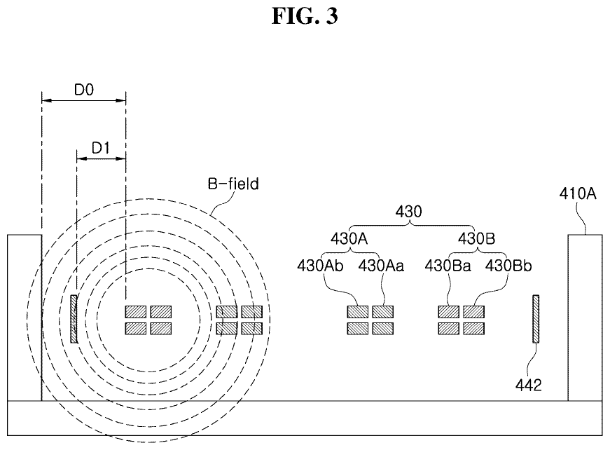

FIG. 3 is a view for explaining linkage of a magnetic field in the plasma generation module 400 in the state in which a metal ring 442 is located between the antenna 430 and the housing 410. Referring to FIG. 3, the metal ring 442 is located between the antenna 430 and the wall 410A of the housing 410. The metal ring 442 increases linkage of a magnetic field generated by the antenna 430. That is, the metal ring 442 may produce an effect of reducing the distance D0 between the antenna 430 and the wall 410A of the housing 410 to D1, which is a distance between the metal ring 442 and the antenna 430.

In order to control the characteristics of the plasma in the edge area of the process chamber 100, the plasma generation module 400 includes a metal ring assembly 440 configured to control linkage of the magnetic field generated by the antenna 430. The metal ring assembly 440 includes a metal ring 442 having a larger diameter than the antenna 430, a vertical drive shaft 444 connected to the upper end of the metal ring 442, and a drive mechanism 446 configured to move the metal ring 442 in the vertical direction Z through the vertical drive shaft 444.

The metal ring 442 is a metal object having a ring shape. The linkage of the magnetic field generated around the antenna 430 is changed by the metal ring 442. When the metal ring 442 is located between the antenna 430 and the wall 410A of the housing 410, the linkage of the magnetic field increases due to coupling between the antenna 430 and the metal ring 442. This produces an effect of reducing the distance between the antenna 430 and the wall 410A of the housing 410. The metal ring 442 may be made of a highly conductive metal in order to achieve coupling with the antenna 430. For example, the metal ring 442 may be made of a Permalloy alloy, which is an alloy of iron (Fe) and nickel (Ni).

The vertical drive shaft 444 connects the metal ring 442 and the drive mechanism 446 to each other. The vertical drive shaft 444 is fixed at one end thereof to the metal ring 442, and extends upward from the upper surface of the metal ring 442 so that the other end thereof passes through the ceiling 410B of the housing 410. The drive mechanism 446 is coupled to the upper surface of the ceiling 410B of the housing 410. As shown in FIG. 1, the drive mechanism 446 may be disposed on the upper surface of the ceiling 410B of the housing 410, and the vertical drive shaft 444 may be coupled to the lower portion of the drive mechanism 446. The drive mechanism 446 may lower the metal ring 442 through the vertical drive shaft 444 so that the metal ring 442 is located between the antenna 430 and the wall 410A of the housing 410, or may raise the metal ring 442 through the vertical drive shaft 444 so that the metal ring 442 is located outside the area of influence of the magnetic field generated by the antenna 430. That is, the drive mechanism 446 may selectively place the metal ring 442 in the space between the antenna 430 and the wall 410A of the housing 410. The drive mechanism 446 may be implemented as a motor or a cylinder.

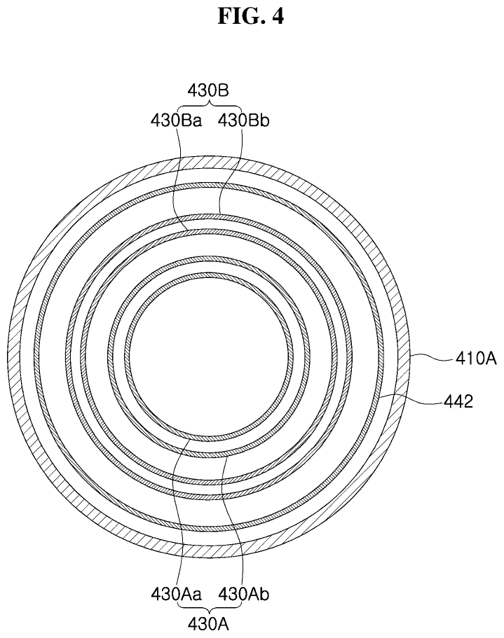

FIG. 4 shows the cross-section taken along line A-A′ in FIG. 1. As shown in FIG. 4, the antenna 430 includes an inner antenna 430A and an outer antenna 430B. The inner antenna 430A includes an inner coil 430Aa and an outer coil 430Ab, and the outer antenna 430B includes an inner coil 430Ba and an outer coil 430Bb. The metal ring 442 may be formed to have a larger diameter than the outer coil 430Bb of the outer antenna 430B. The metal ring 442 may have the same center as the antenna 430 and may have a larger diameter than the outer coil 430Bb of the outer antenna 430B. The linkage of the magnetic field generated by the antenna 430 may be changed by the metal ring 442.

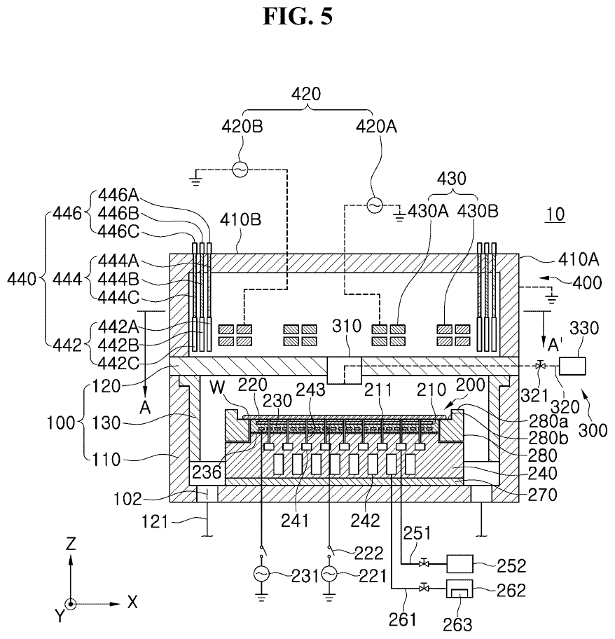

FIG. 5 shows the structure of a substrate processing apparatus 10 including a metal ring assembly 440 including a plurality of metal rings 442A, 442B, and 442C. According to this embodiment, the metal ring 442 may include a plurality of metal rings 442A, 442B, and 442C disposed concentrically with each other while having different diameters. Referring to FIG. 5, the metal rings 442A, 442B, and 442C having different diameters may be located between the antenna 430 and the wall 410A of the housing 410.

The metal ring 442 may include a first metal ring 442A closest to the antenna 430, a second metal ring 442B located outside the first metal ring 442A, and a third metal ring 442C located outside the second metal ring 442B. The vertical drive shaft 444 may include a first vertical drive shaft 444A coupled to the first metal ring 442A, a second vertical drive shaft 444B coupled to the second metal ring 442B, and a third vertical drive shaft 444C coupled to the third metal ring 442C. The drive mechanism 446 includes a first drive mechanism 446A configured to move the first metal ring 442A in the vertical direction Z through the first vertical drive shaft 444A, a second drive mechanism 446B configured to move the second metal ring 442B in the vertical direction Z through the second vertical drive shaft 444B, and a third drive mechanism 446C configured to move the third metal ring 442C in the vertical direction Z through the third vertical drive shaft 444C.

According to this embodiment, at least one of the plurality of metal rings 442A, 442B, and 442C may be selectively located between the antenna 430 and the wall 410A of the housing 410. That is, through individual control of the drive mechanisms 446A, 446B, and 446C, some of the metal rings 442A, 442B, and 442C may be located between the antenna 430 and the wall 410A of the housing 410, and the remaining ones thereof may be located outside the range of the magnetic field generated by the antenna 430.

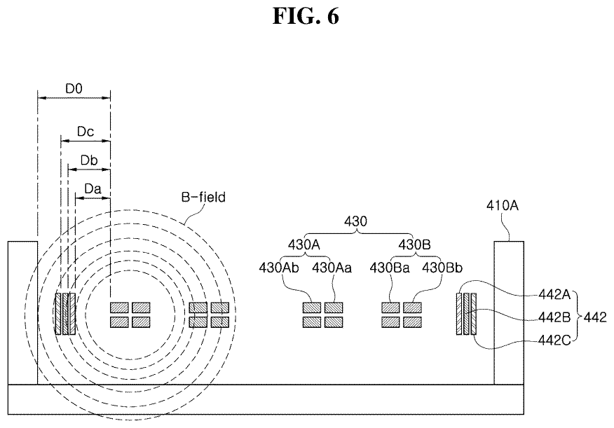

FIG. 6 is a view for explaining linkage of a magnetic field in the plasma generation module 400 in the state in which the plurality of metal rings 442A, 442B, and 442C is located between the antenna 430 and the housing 410. Referring to FIG. 6, the plurality of metal rings 442A, 442B, and 442C is located between the antenna 430 and the wall 410A of the housing 410. The plurality of metal rings 442A, 442B, and 442C increases linkage of a magnetic field generated by the antenna 430. Unlike the state shown in FIG. 6, one of the plurality of metal rings 442A, 442B, and 442C may be located between the antenna 430 and the wall 410A of the housing 410, and the remaining ones thereof may be located outside the space between the antenna 430 and the wall 410A of the housing 410.

When the first metal ring 442A is located between the antenna 430 and the wall 410A of the housing 410, this produces an effect of reducing the distance between the antenna 430 and the wall 410A of the housing 410 to a first distance Da, which is shorter than the original distance D0 between the antenna 430 and the wall 410A of the housing 410. When the second metal ring 442B is located between the antenna 430 and the wall 410A of the housing 410, this produces an effect of reducing the distance between the antenna 430 and the wall 410A of the housing 410 to a second distance Db, which is shorter than the original distance D0 between the antenna 430 and the wall 410A of the housing 410. When the third metal ring 442C is located between the antenna 430 and the wall 410A of the housing 410, this produces an effect of reducing the distance between the antenna 430 and the wall 410A of the housing 410 to a third distance Dc, which is shorter than the original distance D0 between the antenna 430 and the wall 410A of the housing 410.

When the first metal ring 442A is located between the antenna 430 and the wall 410A of the housing 410, first linkage corresponding to the first distance Da, which is the shortest distance, is generated. When the second metal ring 442B is located between the antenna 430 and the wall 410A of the housing 410, second linkage corresponding to the second distance Db, which is longer than the first distance Da, is generated. In this case, the second linkage is less than the first linkage. When the third metal ring 442C is located between the antenna 430 and the wall 410A of the housing 410, third linkage corresponding to the third distance Dc, which is longer than the second distance Db, is generated. In this case, the third linkage is less than the second linkage.

Not only one, but two or more metal rings may be provided so as to be located between the antenna 430 and the wall 410A of the housing 410. Among the two or more metal rings, a metal ring to be located between the antenna 430 and the wall 410A of the housing 410 may be selected in accordance with the plasma distribution characteristics in the edge area of the process chamber 100. That is, a metal ring to be located between the antenna 430 and the wall 410A of the housing 410 is determined from among the plurality of metal rings 442A, 442B, and 442C based on the plasma distribution in the edge area of the process chamber 100.

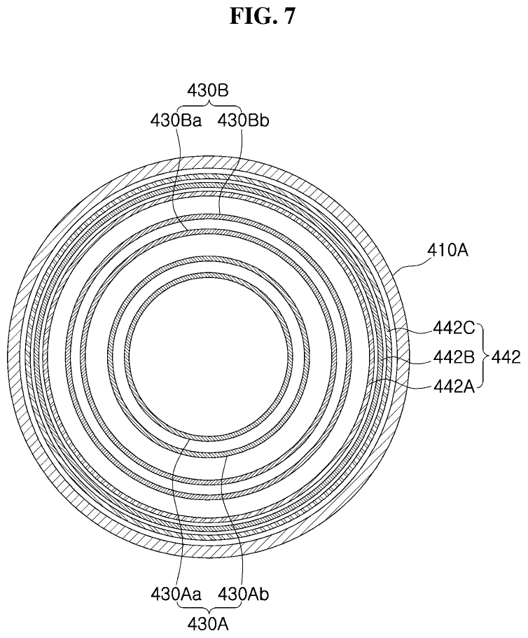

FIG. 7 shows the cross-section taken along line A-A′ in FIG. 5. As shown in FIG. 7, the antenna 430 includes an inner antenna 430A and an outer antenna 430B. The inner antenna 430A includes an inner coil 430Aa and an outer coil 430Ab, and the outer antenna 430B includes an inner coil 430Ba and an outer coil 430Bb. The metal rings 442A, 442B, and 442C may be formed to have a larger diameter than the outer coil 430Bb of the outer antenna 430B. The metal rings 442A, 442B, and 442C may have the same center as the antenna 430 and may have a larger diameter than the outer coil 430Bb of the outer antenna 430B. The first metal ring 442A may be located outside the outer coil 430Bb of the outer antenna 430B, the second metal ring 442B may be located outside the first metal ring 442A, and the third metal ring 442C may be located outside the second metal ring 442B. Among the metal rings 442A, 442B, and 442C, the first metal ring 442A has the smallest diameter, the second metal ring 442B has a diameter larger than the diameter of the first metal ring 442A but smaller than the diameter of the third metal ring 442C, and the third metal ring 442C has the largest diameter. Some of the metal rings 442A, 442B, and 442C may be located between the antenna 430 and the wall 410A of the housing 410, and the remaining ones thereof may be located outside the space between the antenna 430 and the wall 410A of the housing 410.

Linkage of the magnetic field generated by the antenna 430 may be changed depending on combination of the metal rings located in the space between the antenna 430 and the wall 410A of the housing 410 among the metal rings 442A, 442B, and 442C. That is, it is possible to change linkage of the magnetic field generated by the antenna 430 by selecting a metal ring to be located in the space between the antenna 430 and the wall 410A of the housing 410 from among the metal rings 442A, 442B, and 442C through individual control of the drive mechanisms 446A, 446B, and 446C, thereby controlling plasma distribution in the edge area of the process chamber 100.

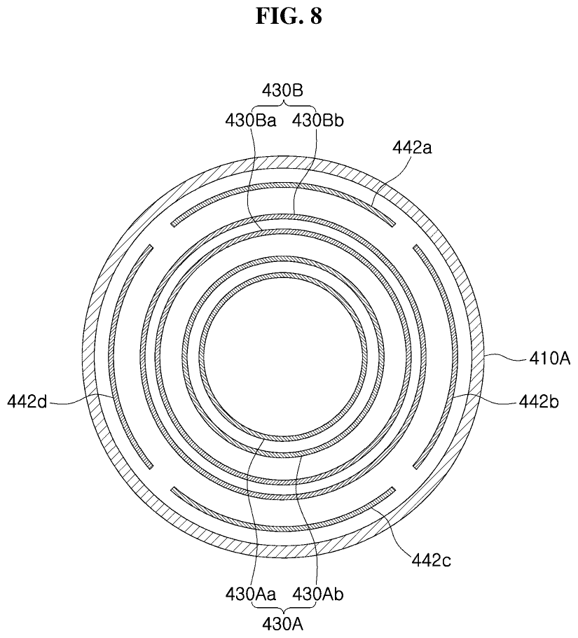

FIG. 8 shows the cross-section taken along line A-A′ in FIG. 1 when the metal ring 442 includes a plurality of ring segments 442a, 442b, 442c, and 442d. The metal ring 442 may include a plurality of ring segments 442a, 442b, 442c, and 442d separated from each other in the horizontal direction. Referring to FIG. 8, the metal ring 442 includes four separate ring segments 442a, 442b, 442c, and 442d, and the remaining components are identical to those in the embodiment shown in FIG. 4. The ring segments 442a, 442b, 442c, and 442d may be symmetrically separate from each other. Each of the ring segments 442a, 442b, 442c, and 442d may be selectively located between the antenna 430 and the wall 410A of the housing 410. Depending on the ring segment located at a position between the antenna 430 and the wall 410A of the housing 410, linkage of the magnetic field generated by the antenna 430 at the corresponding position may be changed, and accordingly, the plasma distribution characteristics at the corresponding position may be changed. The first ring segment 442a may influence plasma distribution at the 12 o'clock position, the second ring segment 442b may influence plasma distribution at the 3 o'clock position, the third ring segment 442c may influence plasma distribution at the 6 o'clock position, and the fourth ring segment 442d may influence plasma distribution at the 9 o'clock position. Each of the ring segments 442a, 442b, 442c, and 442d may be individually coupled to the vertical drive shaft and the drive mechanism so as to be raised and lowered.

In this embodiment, a ring segment to be located between the antenna 430 and the wall 410A of the housing 410 may be determined from among the plurality of ring segments 442a, 442b, 442c, and 442d based on the plasma distribution in the edge area of the process chamber 100.

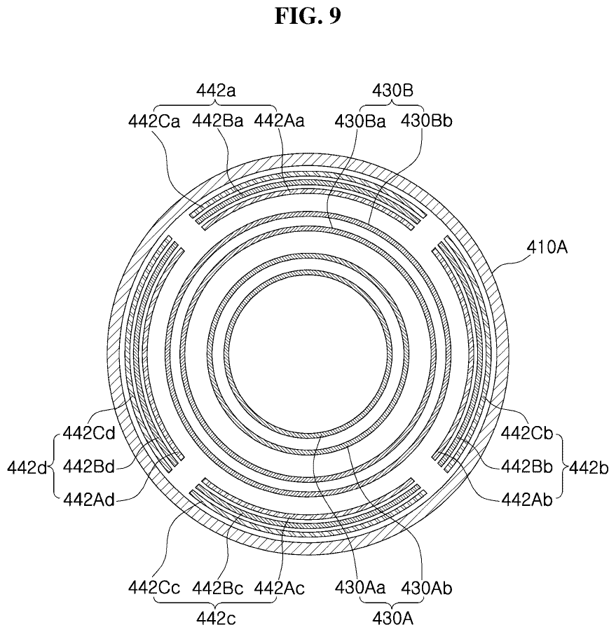

FIG. 9 shows the cross-section taken along line A-A′ in FIG. 5 when the metal ring 442 includes a plurality of metal rings 442A, 442B, and 442C and each of the metal rings 442A, 442B, and 442C includes a plurality of ring segments 442a, 442b, 442c, and 442d. The metal ring 442 may include a plurality of metal rings 442A, 442B, and 442C having different diameters, and each of the metal rings 442A, 442B, and 442C may include a plurality of ring segments 442a, 442b, 442c, and 442d separated from each other in the horizontal direction. Referring to FIG. 9, the metal ring 442 includes four separate ring segments 442a, 442b, 442c, and 442d, and the remaining components are identical to those in the embodiment shown in FIG. 7.

Accordingly, the first ring segment 442a includes first ring sub-segments 442Aa, 442Ba, and 442Ca having different diameters at the 12 o'clock position, the second ring segment 442b includes second ring sub-segments 442Ab, 442Bb, and 442Cb having different diameters at the 3 o'clock position, the third ring segment 442c includes third ring sub-segments 442Ac, 442Bc, and 442Cc having different diameters at the 6 o'clock position, and the fourth ring segment 442d includes fourth ring sub-segments 442Ad, 442Bd, and 442Cd having different diameters at the 9 o'clock position.

In FIG. 9, each of the twelve ring sub-segments may be individually coupled to the vertical drive shaft and the drive mechanism. Through individual control of the drive mechanism, some of the twelve ring sub-segments may be located between the antenna 430 and the wall 410A of the housing 410, and the remaining ones thereof may be located outside the space between the antenna 430 and the wall 410A of the housing 410. Depending on combination of the ring sub-segments located at a position between the antenna 430 and the wall 410A of the housing 410, linkage of the magnetic field generated by the antenna 430 at the corresponding position may be changed, and accordingly, the plasma distribution characteristics at the corresponding position may be changed. That is, it is possible to change linkage of the magnetic field generated by the antenna 430 at each position by selecting a ring sub-segment to be located in the space between the antenna 430 and the wall 410A of the housing 410 from among the ring sub-segments through individual control of the drive mechanisms coupled to the respective ring sub-segments, thereby precisely controlling plasma distribution in the edge area of the process chamber 100.

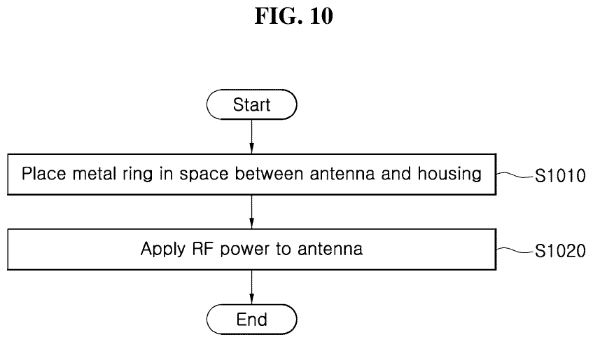

FIG. 10 is a flowchart showing an operation method of a plasma generation module 400 according to the present disclosure. The plasma generation module 400 includes a housing 410, which is disposed on an upper portion of the process chamber 100 having a processing space for processing the substrate W, an antenna 430, which is disposed in the processing space in the housing 410 and applies RF power to the processing space of the process chamber 100, an RF power supply 420, which supplies RF power to the antenna 430, and a metal ring assembly 440, which controls linkage of a magnetic field generated by the antenna 430.

The metal ring assembly 440 includes a metal ring 442, which has a larger diameter than the antenna 430 and is located between the antenna 430 and the wall 410A of the housing 410, a vertical drive shaft 444 connected to the upper end of the metal ring 442, and a drive mechanism 446 configured to move the metal ring 442 in the vertical direction Z through the vertical drive shaft 444.

The operation method of the plasma generation module 400 according to the present disclosure includes a step of placing the metal ring 442 in the space between the antenna 430 and the wall 410A of the housing 410 (S1010) and a step of applying RF power to the antenna 430 (S1020).

In step S1010, the drive mechanism 446 may place the metal ring 442 in the space between the antenna 430 and the wall 410A of the housing 410 through the vertical drive shaft 444. The metal ring 442 is placed between the antenna 430 and the wall 410A of the housing 410, and increases linkage of the magnetic field generated by the antenna 430. That is, the metal ring 442 may produce an effect of reducing the distance D0 between the antenna 430 and the wall 410A of the housing 410 to D1, which is a distance between the metal ring 442 and the antenna 430.

In step S1020, the RF power supply 420 supplies RF power to the antenna 430, and the RF power applied to the antenna 430 generates a magnetic field, thereby exciting process gas present in the process chamber 100. At this time, the plasma distribution characteristics in the edge area of the process chamber 100 are influenced by the magnetic field outside the antenna 430. The magnetic field outside the antenna 430 is varied depending on the distance between the antenna 430 and the wall 410A of the housing 410. The metal ring 442 produces an effect of changing the distance between the antenna 430 and the wall 410A of the housing 410, thereby changing linkage of the magnetic field generated by the antenna 430. That is, plasma distribution in the edge area of the process chamber 100 may be controlled by the metal ring 442.

In the embodiment of the present disclosure, the metal ring 442 is configured to be selectively moved in the vertical direction Z by the drive mechanism 446. That is, the drive mechanism 446 may selectively place the metal ring 442 in the space between the antenna 430 and the wall 410A of the housing 410.

In the embodiment of the present disclosure, the vertical drive shaft 444 extends upward from the upper surface of the metal ring 442 to pass through the ceiling 410B of the housing 410, and the drive mechanism 446 is coupled to the upper surface of the ceiling 410B of the housing 410. The drive mechanism 446 may be implemented as a motor or a cylinder. As shown in FIG. 1, the drive mechanism 446 may be disposed on the upper surface of the ceiling 410B of the housing 410, and the vertical drive shaft 444 may be coupled to the lower portion of the drive mechanism 446. The drive mechanism 446 may lower the metal ring 442 through the vertical drive shaft 444 so that the metal ring 442 is located between the antenna 430 and the wall 410A of the housing 410, or may raise the metal ring 442 through the vertical drive shaft 444 so that the metal ring 442 is located outside the area of influence of the magnetic field generated by the antenna 430. That is, the drive mechanism 446 may selectively place the metal ring 442 in the space between the antenna 430 and the wall 410A of the housing 410.

In the embodiment of the present disclosure, the metal ring 442 may include a plurality of metal rings 442A, 442B, and 442C disposed concentrically with each other while having different diameters. Referring to FIG. 5, the metal rings 442A, 442B, and 442C having different diameters may be located between the antenna 430 and the wall 410A of the housing 410. The metal ring 442 may include a first metal ring 442A closest to the antenna 430, a second metal ring 442B located outside the first metal ring 442A, and a third metal ring 442C located outside the second metal ring 442B. At least one of the plurality of metal rings 442A, 442B, and 442C may be selectively located between the antenna 430 and the wall 410A of the housing 410. That is, through individual control of the drive mechanisms 446A, 446B, and 446C, some of the metal rings 442A, 442B, and 442C may be located between the antenna 430 and the wall 410A of the housing 410, and the remaining ones thereof may be located outside the range of the magnetic field generated by the antenna 430. One or more metal rings may be located between the antenna 430 and the wall 410A of the housing 410, and a metal ring to be located between the antenna 430 and the wall 410A of the housing 410 may be selected in accordance with the plasma distribution characteristics in the edge area of the process chamber 100. That is, a metal ring to be located between the antenna 430 and the wall 410A of the housing 410 is determined from among the plurality of metal rings 442A, 442B, and 442C based on the plasma distribution in the edge area of the process chamber 100.

In the embodiment of the present disclosure, the metal ring 442 may include a plurality of ring segments 442a, 442b, 442c, and 442d separated from each other in the horizontal direction. Referring to FIG. 8, the metal ring 442 includes four separate ring segments 442a, 442b, 442c, and 442d. The ring segments 442a, 442b, 442c, and 442d may be symmetrically separate from each other. Each of the ring segments 442a, 442b, 442c, and 442d may be selectively located between the antenna 430 and the wall 410A of the housing 410. Depending on the ring segment located at a position between the antenna 430 and the wall 410A of the housing 410, linkage of the magnetic field generated by the antenna 430 at the corresponding position may be changed, and accordingly, the plasma distribution characteristics at the corresponding position may be changed. The first ring segment 442a may influence plasma distribution at the 12 o'clock position, the second ring segment 442b may influence plasma distribution at the 3 o'clock position, the third ring segment 442c may influence plasma distribution at the 6 o'clock position, and the fourth ring segment 442d may influence plasma distribution at the 9 o'clock position. Each of the ring segments 442a, 442b, 442c, and 442d may be individually coupled to a vertical drive shaft and a drive mechanism so as to be raised and lowered. A ring segment to be located between the antenna 430 and the wall 410A of the housing 410 may be determined from among the plurality of ring segments 442a, 442b, 442c, and 442d based on the plasma distribution in the edge area of the process chamber 100.

In the embodiment of the present disclosure, the metal ring 442 may be made of a highly conductive metal in order to achieve coupling with the antenna 430. For example, the metal ring 442 may be made of a Permalloy alloy, which is an alloy of iron (Fe) and nickel (Ni).

As is apparent from the above description, according to the present disclosure, the plasma characteristics in the edge area in a processing space in a process chamber may be controlled through a metal ring assembly provided between a housing and an antenna.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A plasma generation module for generating plasma in a substrate processing apparatus configured to process a substrate using plasma, the plasma generation module comprising:
a housing disposed on an upper portion of a process chamber having a processing space for processing the substrate;
an antenna disposed in the processing space in the housing, the antenna being configured to apply radio-frequency (RF) power to the processing space;
an RF power supply configured to supply the RF power to the antenna; and
a metal ring assembly configured to control linkage of a magnetic field generated by the antenna.

2. The plasma generation module as claimed in claim 1, wherein the metal ring assembly comprises:
a metal ring having a larger diameter than the antenna, the metal ring being located between the antenna and a wall of the housing;
a vertical drive shaft connected to an upper end of the metal ring; and
a drive mechanism configured to move the metal ring in a vertical direction through the vertical drive shaft.

3. The plasma generation module according to claim 2, wherein the vertical drive shaft extends upward from an upper surface of the metal ring to pass through a ceiling of the housing, and
wherein the drive mechanism is coupled to an upper surface of the ceiling of the housing.

4. The plasma generation module according to claim 3, wherein the drive mechanism is implemented as a motor or a cylinder.

5. The plasma generation module according to claim 2, wherein the metal ring comprises a plurality of metal rings disposed concentrically with each other while having different diameters.

6. The plasma generation module according to claim 5, wherein a metal ring to be located between the antenna and the wall of the housing is determined from among the plurality of metal rings based on plasma distribution in an edge area of the process chamber.

7. The plasma generation module according to claim 2, wherein the metal ring comprises a plurality of ring segments separated from each other in a horizontal direction.

8. The plasma generation module according to claim 7, wherein a ring segment to be located between the antenna and the wall of the housing is determined from among the plurality of ring segments based on plasma distribution in an edge area of the process chamber.

9. The plasma generation module according to claim 2, wherein the metal ring is made of a Permalloy alloy.

10. A method of operating a plasma generation module for generating plasma in a substrate processing apparatus configured to process a substrate using plasma, wherein the plasma generation module comprises:
a housing disposed on an upper portion of a process chamber having a processing space for processing the substrate;
an antenna disposed in the processing space in the housing, the antenna being configured to apply RF power to the processing space;
an RF power supply configured to supply the RF power to the antenna; and
a metal ring assembly configured to control linkage of a magnetic field generated by the antenna,
wherein the metal ring assembly comprises:
a metal ring having a larger diameter than the antenna, the metal ring being located between the antenna and a wall of the housing;
a vertical drive shaft connected to an upper end of the metal ring; and
a drive mechanism configured to move the metal ring in a vertical direction through the vertical drive shaft, and
wherein the method comprises:
placing the metal ring in a space between the antenna and the wall of the housing; and
applying the RF power to the antenna.

11. The method according to claim 10, wherein the vertical drive shaft extends upward from an upper surface of the metal ring to pass through a ceiling of the housing, and
wherein the drive mechanism is coupled to an upper surface of the ceiling of the housing.

12. The method according to claim 10, wherein the drive mechanism is implemented as a motor or a cylinder.

13. The method according to claim 10, wherein the metal ring comprises a plurality of metal rings disposed concentrically with each other while having different diameters.

14. The method according to claim 13, wherein a metal ring to be located between the antenna and the wall of the housing is determined from among the plurality of metal rings based on plasma distribution in an edge area of the process chamber.

15. The method according to claim 10, wherein the metal ring comprises a plurality of ring segments separated from each other in a horizontal direction.

16. The method according to claim 15, wherein a ring segment to be located between the antenna and the wall of the housing is determined from among the plurality of ring segments based on plasma distribution in an edge area of the process chamber.

17. The method according to claim 10, wherein the metal ring is made of a Permalloy alloy.

18. A substrate processing apparatus for processing a substrate using plasma, the substrate processing apparatus comprising:
a process chamber including a body defining a processing space and a sealing cover covering an open top of the body;
a substrate support member disposed in the body, the substrate support member being configured to support the substrate;
a gas supply module configured to supply process gas to the processing space; and
a plasma generation module configured to apply RF power to the processing space to excite the process gas supplied to the processing space,
wherein the plasma generation module comprises:
a housing disposed on an upper portion of the process chamber;
an antenna disposed in the housing, the antenna being configured to apply the RF power to the processing space;
an RF power supply configured to supply the RF power to the antenna; and
a metal ring assembly configured to control linkage of a magnetic field generated by the antenna,
wherein the metal ring assembly comprises:
a metal ring having a larger diameter than the antenna, the metal ring being located between the antenna and a wall of the housing;
a vertical drive shaft connected to an upper end of the metal ring; and
a drive mechanism configured to move the metal ring in a vertical direction through the vertical drive shaft,
wherein the vertical drive shaft extends upward from an upper surface of the metal ring to pass through a ceiling of the housing,
wherein the drive mechanism is coupled to an upper surface of the ceiling of the housing,
wherein the drive mechanism is implemented as a motor or a cylinder, and
wherein the metal ring is made of a Permalloy alloy.

19. The substrate processing apparatus according to claim 18, wherein the metal ring comprises a plurality of metal rings disposed concentrically with each other while having different diameters, and
wherein a metal ring to be located between the antenna and the wall of the housing is determined from among the plurality of metal rings based on plasma distribution in an edge area of the process chamber.

20. The substrate processing apparatus according to claim 18, wherein the metal ring comprises a plurality of ring segments separated from each other in a horizontal direction, and
wherein a ring segment to be located between the antenna and the wall of the housing is determined from among the plurality of ring segments based on plasma distribution in an edge area of the process chamber.
